(19) United States
(12) Patent Application Publication
(10) Pub. No.: US 2023/0325614 A1
(43) Pub. Date: Oct. 12, 2023

(54) MECHANICAL METAMATERIAL COMPUTER

(71) Applicant: UNIVERSITY OF PITTSBURGH - OF THE COMMONWEALTH, Pittsburgh, PA (US)

(72) Inventor: Amir Alavi, Pittsburgh, PA (US)

(21) Appl. No.: 18/133,879

(22) Filed: Apr. 12, 2023

Related U.S. Application Data
(60) Provisional application No. 63/330,156, filed on Apr. 12, 2022.

(51) Int. Cl. G06G 3/10

(52) U.S. Cl. CPC G06G 3/10

(57) ABSTRACT

A mechanical metamaterial computer or device, comprising a plurality of foldable, triboelectric layers disposed between a first metamaterial surface and a second metamaterial surface. A mechanical metamaterial computer data storage device, comprising a pattern or set of a plurality self-recovering unit cells; wherein each unit cell of a subset of the plurality self-recovering unit cells comprises a built-in contact-electrification mechanism.

### RELATED APPLICATION

This application claims priority benefit under 35 U.S.C. § 119(e) of U.S. Provisional Application No. 63/330,156 filed Apr. 12, 2022, the contents of which are herein incorporated by reference.

### FIELD OF THE DISCLOSURE

### Technical Field

The present disclosure generally relates to the fields of mechanical metamaterials, digital electronics and triboelectricity.

### Background

In the Patent Provisional Application No. 63/048,943 filed Jul. 7, 2020, incorporated by reference herein for all purposes, a self-aware composite mechanical metamaterial was presented with finely tailored and seamlessly integrated microstructures composed of topologically different triboelectric materials for active sensing and energy harvesting.

In a preferred aspect, this disclosure presents “mechanical metamaterials computers (MMCs)”. MMCs can be considered active computing architected materials composed of one or multiple units of so-called cognitive mechanical metamaterials each with a designated digital computing and information storage functionality. Digital computing and information storage may be viewed as “material properties” in cognitive mechanical metamaterials that form the matrix of MMCs Incorporating these functionalities into the fabric of a single mechanical metamaterial system paves the way toward autonomous architected materials. The MMCs of the present disclosure can perform self-powered mechanical-electrical (mechanoelectrical) logic and information storage operations to process the sensed signals and system response. The system response in MMCs is a voltage generated due to the built-in contact-electrification (or triboelectrification) mechanisms between its rationally-designed microlayers. An MMC uses similar built-in contact-electrification mechanisms for information processing and data storage toward achieving cognition and creating a sense-decide-respond loop. Thus, MMCs of the present disclosure can achieve some level of artificial cognition at a constituent material micro level. MMCs build the foundation for mechanical metamaterials sensors (metamechano-sensors), mechanical metamaterials nanogenerators (metamechano-nanogenerators), mechanical metamaterials logic gates (metamechano-logic gates), and mechanical metamaterials memories (metamechano-memories) each with their distinctive engineering applications. Insights into the mechanics, design, and implementation of the scale-independent MMC patterns can be shared among disciplines, ranging from micro/nano-electromechanical systems (MEMS/NEMS), human-machine interfacing, nanorobotics, active flexible electronics to large-scale civil structures. The MMC systems of the present disclosure only use their constituent components to achieve the advanced functionalities. Thus, they establish a direct interaction mechanism between the external environment and electronics, which is a radically different approach from the conventional electrically-controlled logic units Accordingly, MMCs of the present disclosure can be deployed to build a new mechanical metamaterial-inspired circuitry called “metamechanotronic circuit” using a variety of triboelectric materials. Metamechanotronic circuits could construct complex combinational logic operations for sensing, memory, and computation leading to innovations in logic circuits and non-volatile memories. Future potential of the metamechanotronic materials is to substitute traditional electronics to electronics made of metamaterials The metamechanotronic circuits open doors to exporting and transplanting various ideas from digital electronics into the metamaterial domains (e.g. meta-sensors, meta-nanogenerators, meta-logic gates, and meta-memories. Unlike the metamaterials with mechanical logic (mechano-logic) functionality, MMCs could potentially achieve full autonomy through their built-in self-powering mechanical-electrical (mechanoelectrical)-logic to perform digital computations and data storage without an external power supply to operate. A major limitation of the current mechano-logic systems is that they lack a digital electrical output. Since the output of an MMC system is a digital signal, it could potentially compete with the speed and information density of electronic logic. Unlike existing mechano-logic metamaterials that serve merely as mechanical memory units, MMC systems of the present disclosure preferably may be used in digital data storage and non-volatile memories.

### BRIEF SUMMARY OF THE DISCLOSURE

In a preferred aspect, the present disclosure comprises a mechanical metamaterial computer or device, comprising: a plurality of foldable, triboelectric layers disposed between a first metamaterial surface and a second metamaterial surface.

In another preferred aspect of a mechanical metamaterial computer or device of the present disclosure, the plurality of foldable, triboelectric layers comprises a first foldable, triboelectric layer and a second foldable, triboelectric layer.

In yet another preferred aspect of a mechanical metamaterial computer or device of the present disclosure, the first foldable, triboelectric layer is disposed on top of the second foldable, triboelectric layer.

In a further preferred aspect of a mechanical metamaterial computer or device of the present disclosure, each of the foldable, triboelectric layers comprises one or more self-powering mechanoelectrical-logic gates.

In another preferred aspect of a mechanical metamaterial computer or device of the present disclosure, each of the foldable, triboelectric layers comprises contact-separation modes.

In an additional preferred aspect of a mechanical metamaterial computer or device of the present disclosure, each of the foldable, triboelectric layers only generates an electrical signal in a close-and-recover state.

In another preferred aspect of a mechanical metamaterial computer or device of the present disclosure, under uniaxial compressive loading of the first metamaterial surface, each of the foldable, triboelectric layers is in a close-and-recover state and generate electrical signals.

In yet a further preferred aspect of a mechanical metamaterial computer or device of the present disclosure, under clockwise rotation of the first metamaterial surface, the first foldable, triboelectric layer is in a close-and-recover state and generates an electrical signal, and the second foldable, triboelectric layer is in an open-and-recover state and does not generate an electrical signal.

In another preferred aspect of a mechanical metamaterial computer or device of the present disclosure, under counterclockwise rotation of the first metamaterial surface, the first foldable, triboelectric layer is in an open-and-recover state and does not generate an electrical signal, and the second foldable, triboelectric layer is in a closed-and-recover state and generates an electrical signal.

In another preferred aspect, the present disclosure comprises a mechanical metamaterial computer data storage device, comprising: a pattern or set of a plurality self-recovering unit cells; wherein each unit cell of a subset of the plurality self-recovering unit cells comprises a built-in contact-electrification mechanism.

In another preferred aspect of a mechanical metamaterial computer data storage device of the present disclosure, the pattern or set of a plurality self-recovering unit cells comprises a matrix or a 3×3 matrix.

In yet another preferred aspect of a mechanical metamaterial computer data storage device of the present disclosure, the pattern or set of a plurality self-recovering unit cells comprises a first layer of unit cells, a second layer of unit cells and a third layer of unit cells; wherein the second layer of unit cells is disposed between the first and third layers of unit cells.

In another preferred aspect of a mechanical metamaterial computer data storage device of the present disclosure, the second layer of unit cells is disposed between the first and third layers of unit cells.

In a further preferred aspect of a mechanical metamaterial computer data storage device of the present disclosure, each of the first layer, second layer and third layer has a respective and specific stiffness.

In another preferred aspect of a mechanical metamaterial computer data storage device of the present disclosure, under axial loading of the mechanical metamaterial computer data storage device, triboelectrification occurs only within the unit cells with embedded contact-electrification mechanisms in the first layer and the second layer.

In an additional preferred aspect of a mechanical metamaterial computer data storage device of the present disclosure, under axial loading of the mechanical metamaterial computer data storage device, the unit cells in the second layer will buckle but will not generate an electrical signal.

In another preferred aspect of a mechanical metamaterial computer data storage device of the present disclosure, the first, second and third layers have different snapping segment thicknesses, t1, t2 and t3, respectively, that deform sequentially under load such that the mechanical metamaterial computer data storage device produces an alternatively varying voltage signal in quasi-square wave.

In yet another preferred aspect of a mechanical metamaterial computer data storage device of the present disclosure, t1<t2<t3.

In another preferred aspect of a mechanical metamaterial computer data storage device of the present disclosure, trough(s) and crest(s) of the quasi-square wave signal are coded as binary bits of “0” and “1,” respectively, while the time span of the trough and the crest is associated with the number of bits.

In a further preferred aspect of a mechanical metamaterial computer data storage device of the present disclosure, a string of codes “1001” is generated, which represents the decimal “9”.

In another preferred aspect of a mechanical metamaterial computer data storage device of the present disclosure, the mechanical metamaterial computer data storage device comprises either a sequential access memory (SAM) where stored data can be accessed in a deformation sequential order under mechanical stimulations, or a random-access memory (RAM) where data can be accessed in any order.

In yet another preferred aspect of a mechanical metamaterial computer data storage device of the present disclosure, the mechanical metamaterial computer data storage device comprises either a flexible/soft or hard data storage system.

In a further preferred aspect of a mechanical metamaterial computer data storage device of the present disclosure, the mechanical metamaterial computer data storage device provides a low-cost, non-volatile, and long-term storage solutions for specific cyber threats and large-capacity data storage applications.

### BRIEF DESCRIPTION OF THE DRAWINGS

For the present disclosure to be easily understood and readily practiced, the present disclosure will now be described for purposes of illustration and not limitation in connection with the following figures, wherein:

FIG. 1 shows a composition of a preferred origami-inspired MMC of the present disclosure.

FIG. 2 shows the working mechanism of a preferred, origami-inspired MMC of the present disclosure designed to perform self-powered digital computations.

FIG. 3a shows a composition of a preferred MMC of the present disclosure.

FIGS. 3b-3e show the amplitude and frequency of triggering mechanical inputs for the MMC of FIG. 3a.

FIGS. 4a-4d show a preferred MMC data storage device of the present disclosure featuring mechanically-responsive (mechano-responsive) data storage functionality.

FIG. 5 shows depicts a mechanical metamaterial tree of knowledge.

FIG. 6 is a schematic of a functional hierarchy for mechanical metamaterial devices.

### DETAILED DESCRIPTION

Digital Computation with MMCs

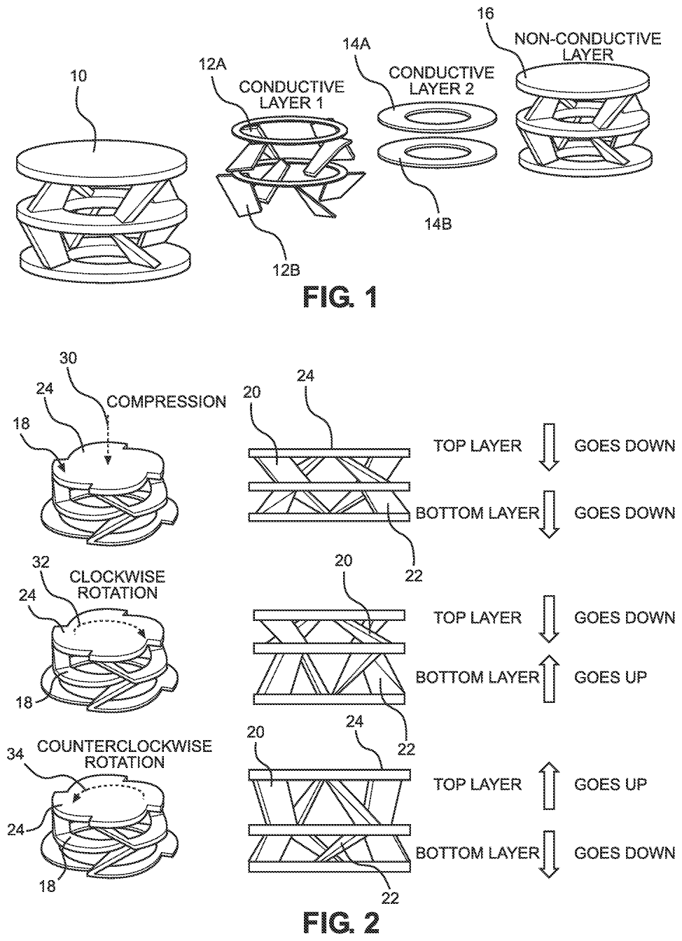

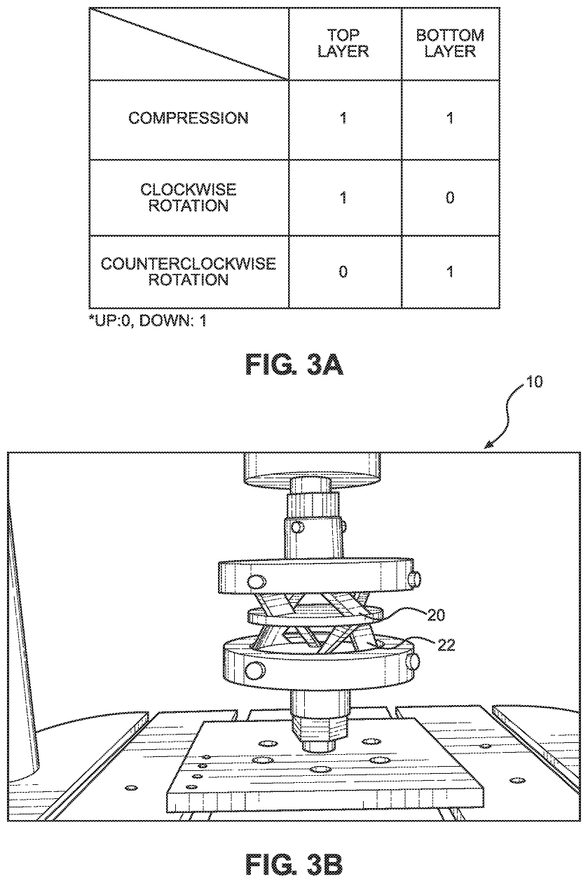

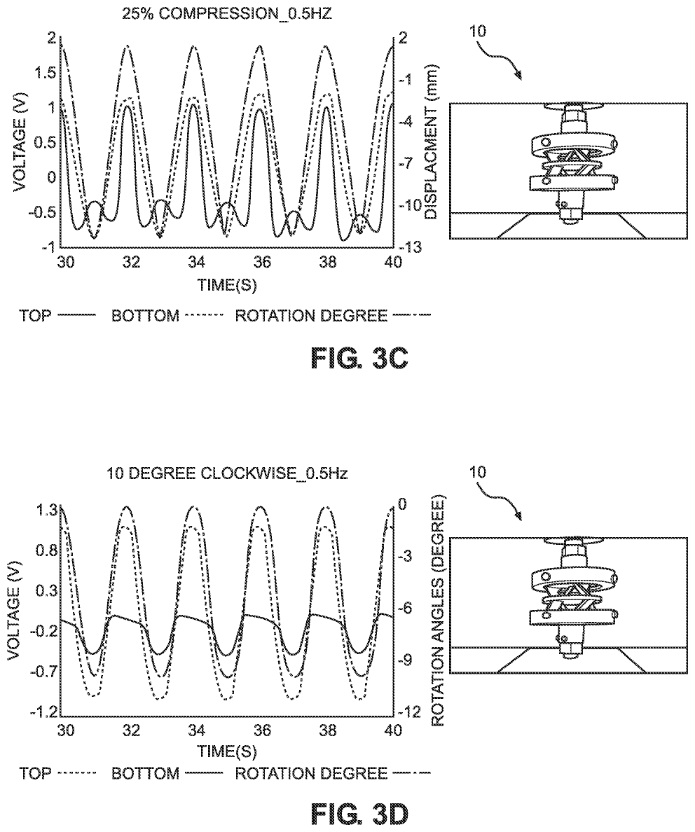

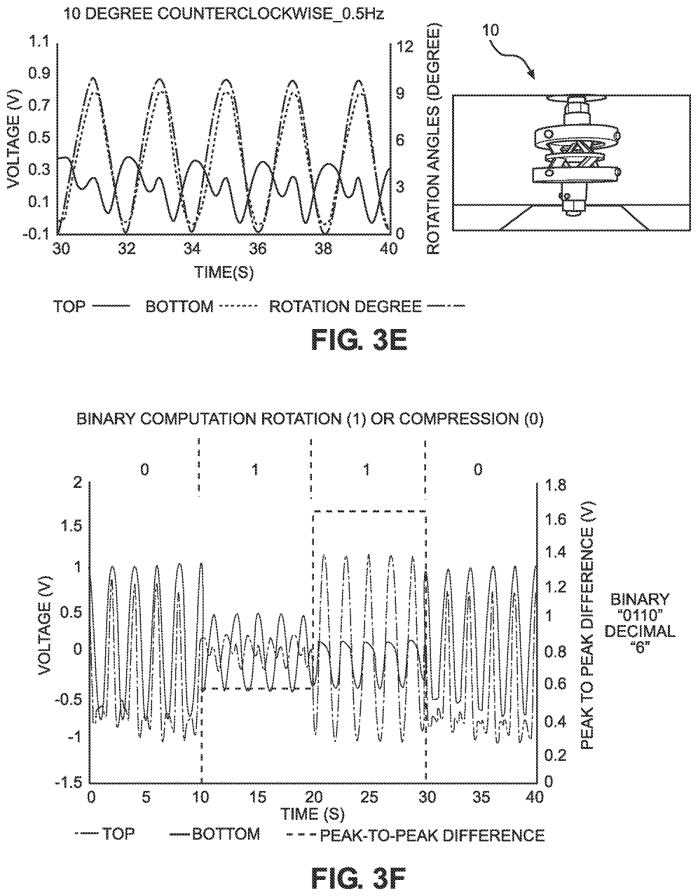

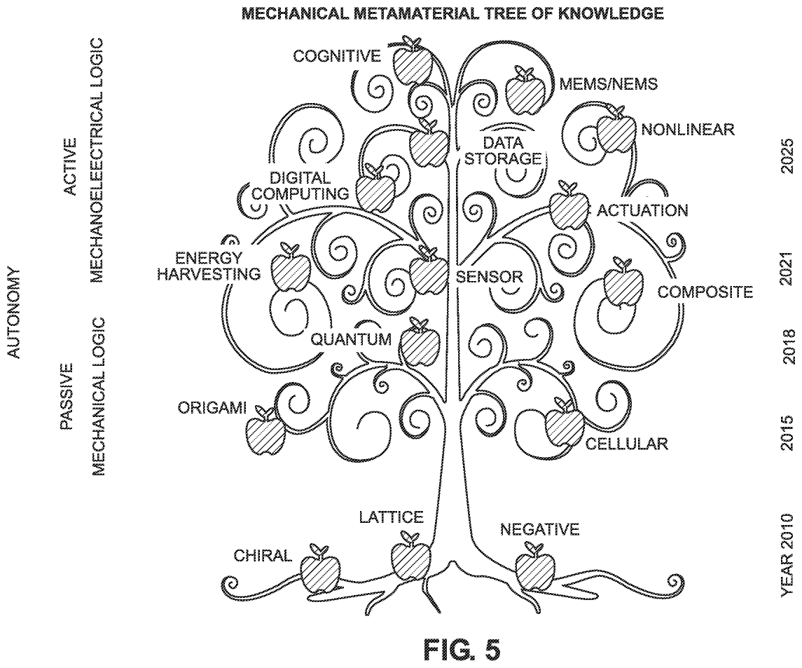

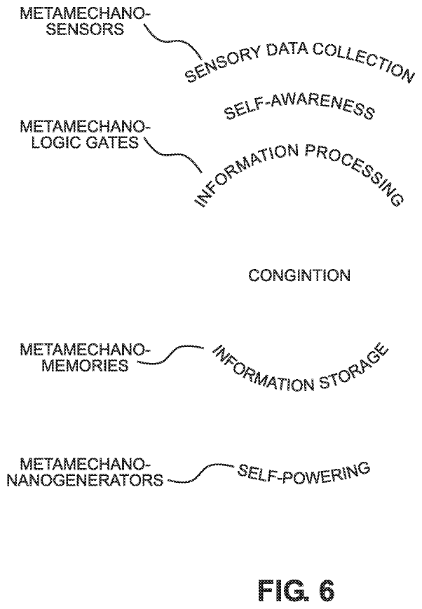

As depicted in FIGS. 5-6, a crucial step to achieve cognitive mechanical metamaterials with full autonomy is to incorporate digital computing and information storage functionalities into their texture. An MMC system consists of a single or multiple units of cognitive mechanical metamaterials composed of multiple triboelectric layers. FIG. 1 shows a composition of a preferred origami-inspired MMC 10 of the present disclosure having conductive layers 12a-12b and 14a-14b and non-conductive layer 16. The MMC presented in this disclosure possesses self-powering mechanoelectrical-logic gates for digital computation. FIG. 2 shows the working mechanism of a preferred, origami-inspired MMC 10 of the present disclosure designed to perform self-powered digital computations. MMC 10 is designed with self-recovering, multi-stimuli responsive unit cells 18 and a two-layer structure having a first or top layer 20 and second or bottom layer 22 to achieve various mechanical states under different types of external loading. Under shear and uniaxial stresses applied to the top metamaterial surface 24, different buckling deformation modes can be realized. Each deformation mode activates the contact-electrification in a specific layer resulting in a distinct electrical signal, which will be used for digital computations. For instance, the MMC 10 shown in FIGS. 1, 2 and 3a-3e is designed with contact-separation modes for the top layer 20 and bottom layer 22. Each of top layer 20 and bottom layer 22 only generates a signal in a close-and-recover state. Under uniaxial compressive loading 30, both layers 20, 22 of MMC 10 travel downward and are in a close-and-recover state and generate electrical signals. When a clockwise rotation 32 is applied, top layer 20 travels downward and is in close-and-recover state, and bottom layer 22 travels upward and is in open-and-recover state. Therefore, only top layer 20 generates an electric signal for a clockwise rotation mechanical input 32. When counterclockwise rotation 34 is applied, top layer 20 travels upward and is in open-and-recover state, and bottom layer 22 travels downward and is in close-and-recover state. Thus, only bottom layer 22 generates an electric signal for a counterclockwise rotation mechanical input 34. Each of the mechanical inputs can be realized with the distinctive voltage patterns generated by the structural channels of MMC 10, as shown in FIG. 2. The generated signals can then be translated into binary signals for digital computation, as shown in Table 1. The MMCs 10 can synthesize discrete mechanical configurations to realize all digital logic gates and compute Boolean logic operations (AND, OR, NAND, NOR, XOR, XNOR, NOT, and Buffer). The proposed formulation of digital logic in the MMCs 10 intrinsically couples the mechanical buckling modes with the distinctive signatures and amplitudes of the electrical signals generated by the metamechanotronic metamaterials. The beauty of the mechanoelectrical-logic approach of the present disclosure is that it can simultaneously realize the type (compression 30, clockwise rotation 32, counterclockwise rotation 34) and the amplitude and frequency of the triggering mechanical inputs, as shown in FIG. 3a-FIG. 3e. Typical amplitude-shift keying (ASK) and frequency-shift keying (FSK) methods can be used to translate the electrical response of the designed metamechanotronic structures into binary digital signals due to a series of triggering mechanical signals with different amplitudes and frequencies. For instance, the MMC system shown in FIG. 3a-FIG. 3e generates electrical signals with different amplitudes under different mechanical states as shown in FIGS. 3b-3d. The amplitude of the wave signals can be coded as binary bits of “0” and “1. In this schematic design, a string of codes “0110” is generated, which represents the decimal “6” (FIG. 3e). By changing the mechanical state, any binary data can be processed with such MMCs.

Data Storage with MMCs

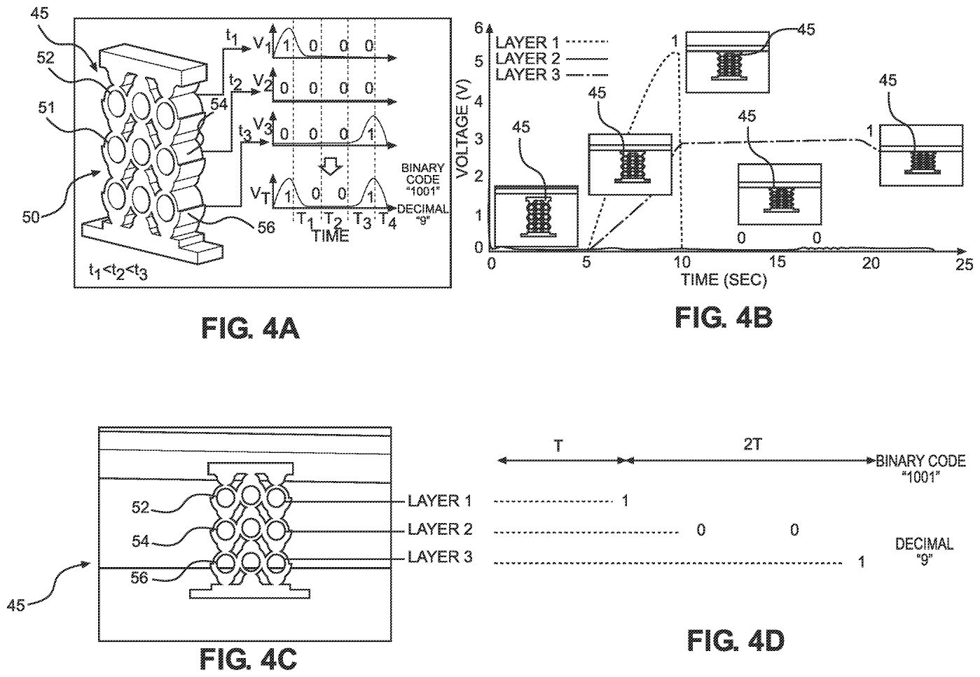

Information storage is an important functionality to produce a sense-decide-respond loop in an active metamaterial system. The current studies present merely a “mechanical” information storage by leveraging the bistability of the mechanical metamaterial structures. FIGS. 4a-4d show a preferred MMC data storage device 45 of the present disclosure featuring mechanically-responsive (mechano-responsive) data storage functionality. MMC mechano-responsive data storage device 45 comprises a pattern or set of self-recovering unit cells 51 that form matrix 50. The structure can be rationally designed in a way that only designated unit cells 51 will have built-in contact-electrification mechanism. FIG. 4a shows a schematic representation of MMC data storage device 45 with three layers 52, 54, 56, wherein each layers 52, 54 and 56 has a respective and specific stiffness. As the metamaterial structure 45 is loaded, triboelectrification occurs only within the cells 51 with embedded contact-electrification mechanism (not shown) in the top layer 52 and the bottom layer 56. See FIGS. 4b and 4c. Under axial loading, the unit cells 51 in the second layer 54 will buckle but will not generate a signal, see FIG. 4c As the three layers 52, 54, 56 with different snapping segment thicknesses (t) deform sequentially (where preferably t₁<t₂<t₃), the entire metamaterial structure 45 will produce alternatively varying voltage signal in quasi-square wave, see FIG. 4c. The trough and crest of the quasi-square wave signal can be coded as binary bits of “0” and “1,” respectively, while the time span of the trough and the crest is associated with the number of bits. In a preferred design of the present disclosure, a string of codes “1001” is generated, which represents the decimal “9” see FIG. 4c. MMC data storage device 45 can be considered as new class of sequential access memory (SAM) where stored data can be accessed in a deformation sequential order under mechanical stimulations. The stiffness of MMC data storage device 45 can be rationally designed so that it can serve as either a flexible/soft or hard data storage system. Similar to advanced SAM technologies (e.g. IBM LTO 9 drive), metamechanotronic mechano-responsive data storage devices 45 can provide low-cost, non-volatile, and long-term storage solutions for specific cyber threats and large-capacity data storage applications. The data storage density of MMC device 45 can be higher than emerged technologies such as Blu-ray Disc because of the high flexibility in the rational design of their microstructures. In addition, an MMC of the present disclosure can be rationally designed as a random-access memory (RAM) where data can be accessed in any order.

In the foregoing Detailed Description, various features are grouped together in a single embodiment to streamline the disclosure. This method of disclosure is not to be interpreted as reflecting an intention that the claimed embodiments of the disclosure require more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separate embodiment.

What is claimed is:

1. A mechanical metamaterial computer or device, comprising:
a plurality of foldable, triboelectric layers disposed between a first metamaterial surface and a second metamaterial surface.

2. The mechanical metamaterial computer or device of claim 1, wherein the plurality of foldable, triboelectric layers comprises a first foldable, triboelectric layer and a second foldable, triboelectric layer.

3. The mechanical metamaterial computer or device of claim 2, wherein the first foldable, triboelectric layer is disposed on top of the second foldable, triboelectric layer.

4. The mechanical metamaterial computer or device of claim 1, wherein each of the foldable, triboelectric layers comprises one or more self-powering mechanoelectrical-logic gates.

5. The mechanical metamaterial computer or device of claim 1, wherein each of the foldable, triboelectric layers comprises contact-separation modes.

6. The mechanical metamaterial computer or device of claim 1, wherein each of the foldable, triboelectric layers only generates an electrical signal in a close-and-recover state.

7. The mechanical metamaterial computer or device of claim 1, wherein under uniaxial compressive loading of the first metamaterial surface, each of the foldable, triboelectric layers is in a close-and-recover state and generate electrical signals.

8. The mechanical metamaterial computer or device of claim 3, wherein under clockwise rotation of the first metamaterial surface, the first foldable, triboelectric layer is in a close-and-recover state and generates an electrical signal, and the second foldable, triboelectric layer is in an open-and-recover state and does not generate an electrical signal.

9. The mechanical metamaterial computer or device of claim 3, wherein under counterclockwise rotation of the first metamaterial surface, the first foldable, triboelectric layer is in an open-and-recover state and does not generate an electrical signal, and the second foldable, triboelectric layer is in a closed-and-recover state and generates an electrical signal.

10. A mechanical metamaterial computer data storage device, comprising:
a pattern or set of a plurality self-recovering unit cells; wherein each unit cell of a subset of the plurality self-recovering unit cells comprises a built-in contact-electrification mechanism.

11. The mechanical metamaterial computer data storage device of claim 10, wherein, the pattern or set of a plurality self-recovering unit cells comprises a matrix or a 3×3 matrix.

12. The mechanical metamaterial computer data storage device of claim 10 wherein, the pattern or set of a plurality self-recovering unit cells comprises a first layer of unit cells, a second layer of unit cells and a third layer of unit cells; wherein the second layer of unit cells is disposed between the first and third layers of unit cells.

13. The mechanical metamaterial computer data storage device of claim 12 wherein, the second layer of unit cells is disposed between the first and third layers of unit cells.

14. The mechanical metamaterial computer data storage device of claim 12 wherein, each of the first layer, second layer and third layer has a respective and specific stiffness.

15. The mechanical metamaterial computer data storage device of claim 12 wherein, under axial loading of the mechanical metamaterial computer data storage device, triboelectrification occurs only within the unit cells with embedded contact-electrification mechanisms in the first layer and the second layer.

16. The mechanical metamaterial computer data storage device of claim 12, wherein, under axial loading of the mechanical metamaterial computer data storage device, the unit cells in the second layer will buckle but will not generate an electrical signal.

17. The mechanical metamaterial computer data storage device of claim 12, wherein, the first, second and third layers have different snapping segment thicknesses, t1, t2 and t3, respectively, that deform sequentially under load such that the mechanical metamaterial computer data storage device produces an alternatively varying voltage signal in quasi-square wave.

18. The mechanical metamaterial computer data storage device of claim 17 wherein, t1<t2<t3.

19. The mechanical metamaterial computer data storage device of claim 17, wherein, trough(s) and crest(s) of the quasi-square wave signal are coded as binary bits of “0” and “1,” respectively, while the time span of the trough and the crest is associated with the number of bits.

20. The mechanical metamaterial computer data storage device of claim 19 wherein, a string of codes “1001” is generated, which represents the decimal “9”.

21. The mechanical metamaterial computer data storage device of claim 12, wherein, the mechanical metamaterial computer data storage device comprises either a sequential access memory (SAM) where stored data can be accessed in a deformation sequential order under mechanical stimulations, or a random-access memory (RAM) where data can be accessed in any order.

22. The mechanical metamaterial computer data storage device of claim 12, wherein, the mechanical metamaterial computer data storage device comprises either a flexible/soft or hard data storage system.

23. The mechanical metamaterial computer data storage device of claim 12, wherein, the mechanical metamaterial computer data storage device provides a low-cost, non-volatile, and long-term storage solutions for specific cyber threats and large-capacity data storage applications.
